(19) United States
(12) Patent Application Publication
(10) Pub. No.: US 2015/0366102 A1
(43) Pub. Date: Dec. 17, 2015

(54) ELECTRONIC CIRCUIT APPARATUS AND METHOD FOR MANUFACTURING ELECTRONIC CIRCUIT APPARATUS

(71) Applicant: IBIDEN CO., LTD., Ogaki (JP)

(72) Inventors: Teruyuki ISHIHARA, Ogaki (JP); Haruhiko MORITA, Ogaki (JP); Takashi KARIYA, Ogaki (JP)

(73) Assignee: IBIDEN CO., LTD., Ogaki (JP)

(21) Appl. No.: 14/737,943

(22) Filed: Jun. 12, 2015

(30) Foreign Application Priority Data
Jun. 13, 2014 (JP) 2014-122318

(51) Int. Cl. H05K 7/20; H05K 3/42; H05K 3/46

(52) U.S. Cl. CPC H05K 7/205; H05K 3/4644; H05K 3/429

(57) ABSTRACT

An electronic circuit apparatus includes a circuit substrate, a heat generating component positioned on the circuit substrate, a metal plate forming a portion of an inner layer of the circuit substrate and protruding from a side surface of the circuit substrate such that the metal plate has an exposed portion exposed to outside the circuit substrate, and an external component connected to the exposed portion of the metal plate and including one of an external heat dissipation component and an external cooling component.

### CROSS-REFERENCE TO RELATED APPLICATIONS

The present application is based upon and claims the benefit of priority to Japanese Patent Application No. 2014-122318, filed Jun. 13, 2014, the entire contents of which are incorporated herein by reference.

### BACKGROUND OF THE INVENTION

1. Field of the Invention

The present invention relates to an electronic circuit apparatus in which a heat generating component is mounted on a circuit substrate, and to a method for manufacturing the electronic circuit apparatus.

2. Description of Background Art

In an electronic circuit apparatus, heat generating component may be mounted on a circuit substrate, and the circuit substrate may include a built-in heat pipe (for example, see Japanese Patent Laid-Open Publication No. 2000-138485). The entire contents of this publication are incorporated herein by reference.

### SUMMARY OF THE INVENTION

According to one aspect of the present invention, an electronic circuit apparatus includes a circuit substrate, a heat generating component positioned on the circuit substrate, a metal plate forming a portion of an inner layer of the circuit substrate and protruding from a side surface of the circuit substrate such that the metal plate has an exposed portion exposed to outside the circuit substrate, and an external component connected to the exposed portion of the metal plate and including one of an external heat dissipation component and an external cooling component.

According to another aspect of the present invention, a method for manufacturing an electronic circuit apparatus includes forming a circuit substrate having a metal plate forming a portion of an inner layer of the circuit substrate, removing a portion of the circuit substrate such that the metal plate has an exposed portion exposed to outside the circuit substrate and protruding from a side surface of the circuit substrate, connecting to the exposed portion of the metal plate an external component including one of an external heat dissipation component and an external cooling component, and positioning a heat generating component on the circuit substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view illustrating an internal structure of electronic equipment that includes an electronic circuit apparatus according to a first embodiment of the present invention;

FIG. 2A is a plan view of the electronic circuit apparatus;

FIG. 2B is a cross-sectional view of the electronic circuit apparatus along a line A-A;

FIG. 3 is a cross-sectional view of a circuit substrate;

FIG. 4A-4C are cross-sectional views illustrating manufacturing processes of the circuit substrate;

FIG. 5A-5C are cross-sectional views illustrating manufacturing processes of the circuit substrate;

FIG. 6A-6C are cross-sectional views illustrating manufacturing processes of the circuit substrate;

FIG. 7A-7C are cross-sectional views illustrating manufacturing processes of the circuit substrate;

FIGS. 8A and 8B are cross-sectional views illustrating manufacturing processes of the circuit substrate;

FIGS. 9A and 9B are cross-sectional views illustrating manufacturing processes of the circuit substrate;

FIGS. 10A and 10B are cross-sectional views illustrating manufacturing processes of the circuit substrate;

FIGS. 11A and 11B are cross-sectional views illustrating manufacturing processes of the circuit substrate;

FIG. 12 is a cross-sectional view illustrating a manufacturing process of the circuit substrate;

FIG. 13A is a plan view of an electronic circuit apparatus according to a second embodiment;

FIG. 13B is a cross-sectional view of the electronic circuit apparatus along a line B-B;

FIG. 14 is a cross-sectional view of a circuit substrate;

FIG. 15A-15D are cross-sectional views illustrating manufacturing processes of the circuit substrate;

FIG. 16A-16C are cross-sectional views illustrating manufacturing processes of the circuit substrate;

FIG. 17A-17C are cross-sectional views illustrating manufacturing processes of the circuit substrate;

FIGS. 18A and 18B are cross-sectional views illustrating manufacturing processes of the circuit substrate;

FIGS. 19A and 19B are cross-sectional views illustrating manufacturing processes of the circuit substrate;

FIGS. 20A and 20B are cross-sectional views illustrating manufacturing processes of the circuit substrate; and

FIGS. 21A and 21B are cross-sectional views illustrating manufacturing processes of the circuit substrate.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

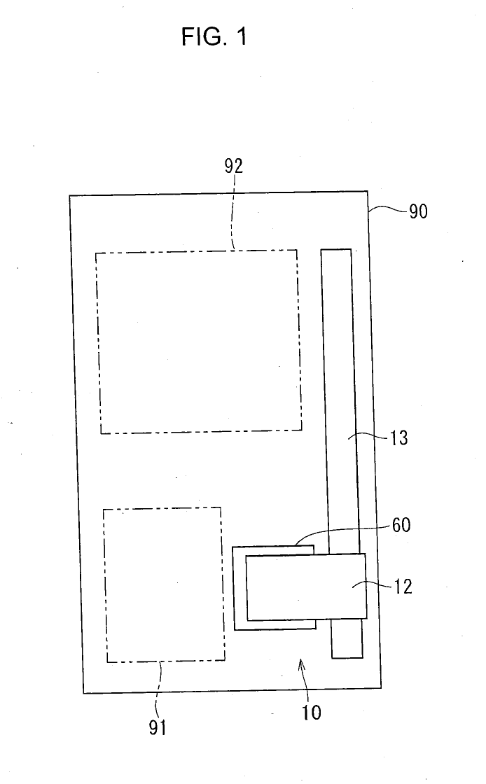

In the following, a first embodiment of the present invention is described based on FIG. 1-12. An electronic circuit apparatus 10 of the present embodiment is included in electronic equipment 90 illustrated in FIG. 1. The electronic equipment 90 is, for example, a cellular phone, a notebook PC, or the like and includes, in addition to the electronic circuit apparatus 10, a battery 91, a liquid crystal display device 92, and the like.

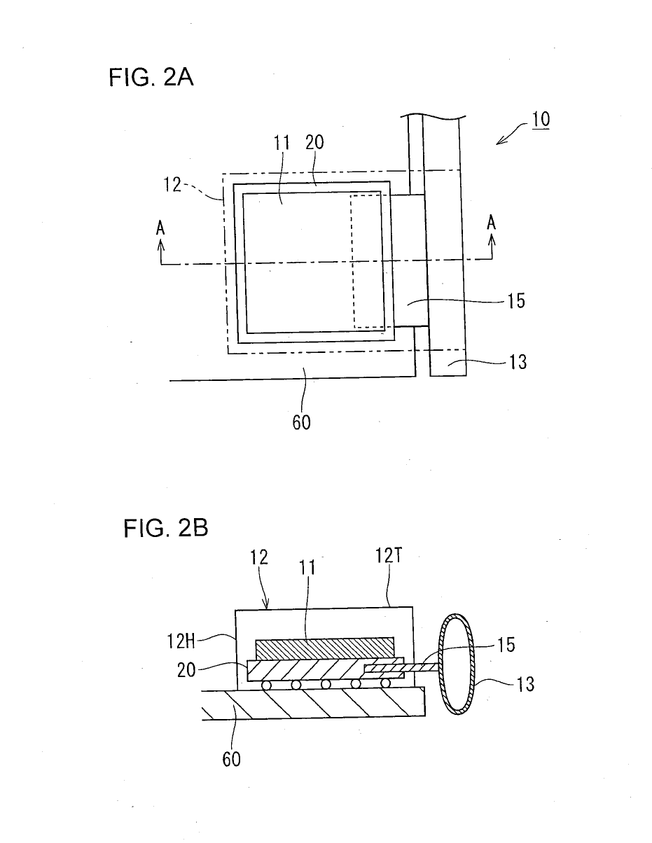

As illustrated in FIG. 2A, the electronic circuit apparatus 10 includes a circuit substrate 20 and a support substrate 60 that supports the circuit substrate 20. The circuit substrate 20 is a CSP (Chip Size Package) having the same size as a chip. A semiconductor element 11 as a “heat generating component” according to an embodiment of the present invention is mounted on the circuit substrate 20. The support substrate 60 is a motherboard. The circuit substrate 20 and the support substrate 60 are connected by solder.

As illustrated in FIG. 2B, the circuit substrate 20 is shielded by a shield can 12 that corresponds to a “shield member” according to an embodiment of the present invention. The shield can 12 has a ceiling wall (12T) that covers upper sides of the circuit substrate 20 and the semiconductor element 11, and a surrounding wall (12H) that surrounds four sides of the circuit substrate 20. A leg portion of the surrounding wall (20H) is fixed on the support substrate 60. Specifically, a portion of the ceiling wall (12T) protrudes to the sides of the circuit substrate 20 and the support substrate 60. The shield can 12 is formed, for example, by processing a sheet metal having a thickness of about 0.2 mm.

As illustrated in FIG. 1, the electronic circuit apparatus 10 has a heat pipe 13 as an “external cooling member” according to an embodiment of the present invention on one side of the support substrate 60 and the circuit substrate 20. The heat pipe 13 has a structure in which meshes are laid on an inner wall of a hollow tube in which an operating fluid is sealed. One end portion of the heat pipe 13 is positioned on one side of the circuit substrate 20.

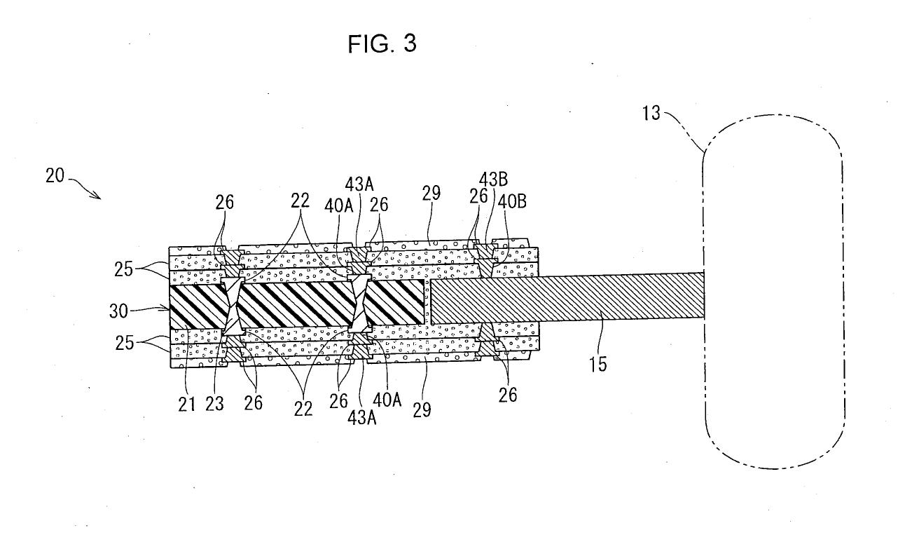

As illustrated in FIG. 3, the circuit substrate 20 has a multilayer structure in which build-up insulating layers 25 and build-up conductor layers 26 are alternately laminated on both front and back surfaces of a core substrate 21 and outermost build-up conductor layers 26 are respectively covered by solder resist layers 29. The core substrate 21 has a thickness of about 150 μm. Core conductor layers 22 are respectively formed on both the front and back surfaces of the core substrate 21. The build-up insulating layers 25 are each formed of an insulating material and each have a thickness of about 25 μm. The build-up conductor layers 26 are each formed of metal (such as copper) and each have a thickness of about 15 μm. The solder resist layers 29 each have a thickness of about 15 μm.

The front side core conductor layer 22 and the back side core conductor layer 22 are connected by a through-hole conductor 23 that penetrates through the core substrate 21. Electrical conductive vias (40A, 43A) are formed in the build-up insulating layers 25. The innermost build-up conductor layer 26, which is closest to the core substrate 21, and the core conductor layer 22 are connected by the electrical conductive via (40A), and the build-up conductor layers (26, 26) that are adjacent to each other in a lamination direction are connected by the electrical conductive via (43A).

As illustrated in FIG. 3, in the circuit substrate 20 of the present embodiment, the core substrate 21 is a metal plate built-in insulating layer 30 that has a built-in metal plate 15. Specifically, a portion of the metal plate 15 forms a region ranging from a portion of the core substrate 21 positioned below the semiconductor element 11 to an edge on the side close to the heat pipe 13; and the rest of the metal plate 15, as illustrated in FIG. 1B, protrudes from a side surface of the circuit substrate 20 and is exposed to the outside. A thickness of the metal plate 15 is substantially the same as the thickness of the core substrate 21 and is about 150 μm.

Thermal conductive vias (40B, 43B) are formed in portions of the build-up insulating layers 25 that overlap with the metal plate 15. The innermost build-up conductor layer 26 and the metal plate 15 are connected by the thermal conductive via (40B), and the build-up conductor layers (26, 26) that are adjacent to each other in the lamination direction are connected by the thermal conductive via (43B).

As illustrated in FIG. 2B, the portion of the metal plate 15 that is exposed to the outside of the circuit substrate 20 penetrates through the surrounding wall (12H) of the shield can 12 and is connected to the heat pipe 13, for example, by soldering. The metal plate 15 may also be connected to the heat pipe 13 by a conductive tape. The contact between the metal plate 15 and the heat pipe 13 may also be mechanically achieved by sandwiching the metal plate 15 between a case of the electronic equipment 90 and the heat pipe 13.

Next, a method for manufacturing the electronic circuit apparatus 10 is described. In the method for manufacturing the electronic circuit apparatus 10, first, the semiconductor element 11 is mounted on a CSP as the circuit substrate 20, and the CSP is solder-connected to a motherboard as the support substrate 60. Then, the shield can 12 is fixed on the support substrate 60, and the metal plate 15 that protrudes from the circuit substrate 20 penetrates through the shield can 12 and is connected to the heat pipe 13. Thereby, the electronic circuit apparatus 10 is manufactured.

The circuit substrate 20 is manufactured as follows.

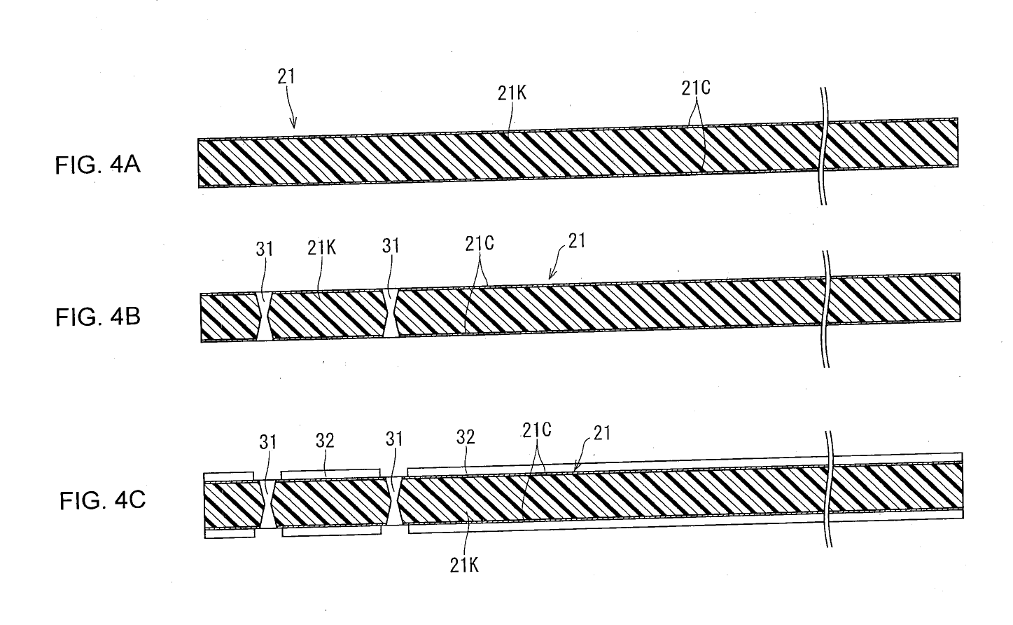

(1) As illustrated in FIG. 4A, first, the core substrate 21 is prepared. The core substrate 21 is obtained by laminating a copper foil (21C) on both front and back surfaces of an insulating base material (21K) that is made of epoxy resin or BT (bismaleimide triazine) resin and a reinforcing material such as a glass cloth.

(2) As illustrated in FIG. 4B, a core through hole 31 is drilled by irradiating, for example, CO2 laser to the core substrate 21 from the front side and the back side.

(3) An electroless plating treatment is performed. An electroless plating film (not illustrated in the drawings) is formed on the copper foil (21C) and on an inner surface of the core through hole 31.

(4) As illustrated in FIG. 4C, a plating resist 32 of a predetermined pattern is formed on the electroless plating film on the copper foil (21C).

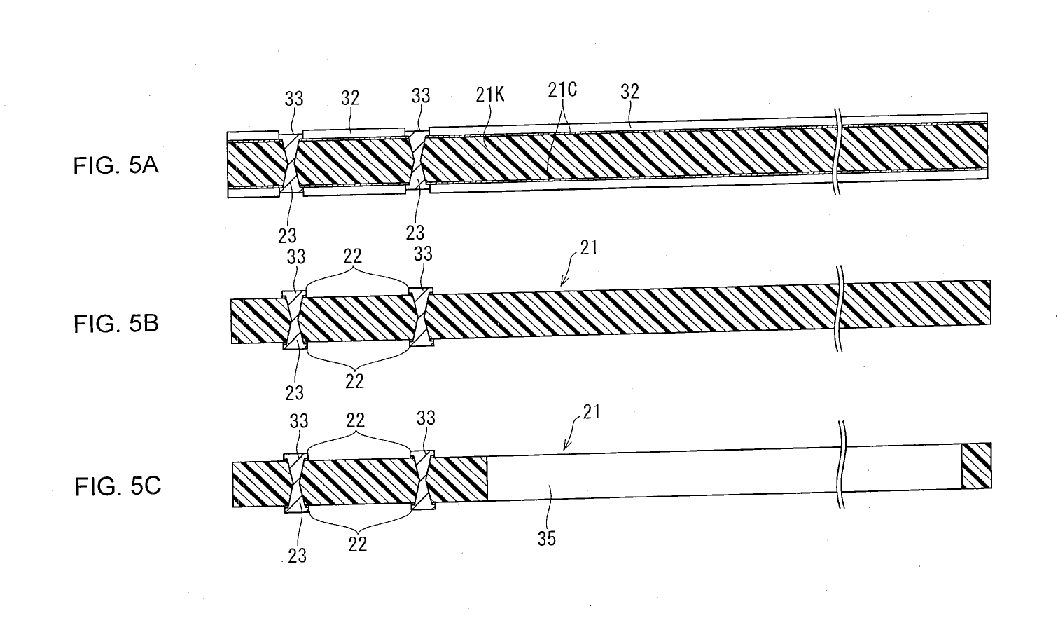

(5) As illustrated FIG. 5A, an electrolytic plating treatment is performed. The core through hole 31 is filled with electrolytic plating and the through-hole conductor 23 is formed. Further, an electrolytic plating film 33 is formed on a portion of the electroless plating film (not illustrated in the drawings) on both the front and back surfaces of the core substrate 21, the portion being exposed from the plating resist 32.

(6) The plating resist 32 is peeled off using 5% NaOH, and the electroless plating film (not illustrated in the drawings) and the copper foil (21C), which are below the plating resist 32, are removed. As illustrated in FIG. 5B, the core conductor layers 22 are respectively formed on the front and back surfaces of the core substrate 21 by the remaining electrolytic plating film 32, electroless plating film and copper foil (21C) (see FIG. 5A; illustration thereof is omitted in FIG. 5B).

(7) As illustrated in FIG. 5C, by router processing or the like, a central portion of the core substrate 21 is cut off and an accommodation hole 35 is formed.

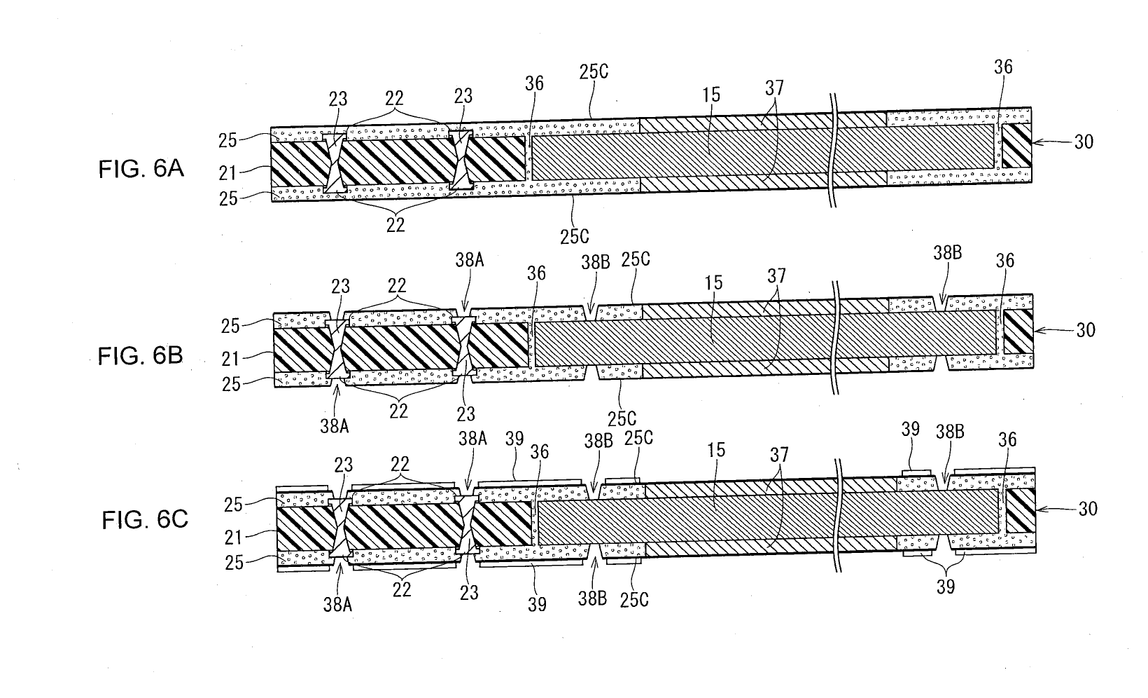

(8) The metal plate 15 is accommodated in the accommodation hole 35, and a prepreg (a resin sheet of a B-stage formed by impregnating a core material with resin) as a build-up insulating layer 25 is laminated from both the front and back surfaces of the core substrate 21. In doing so, a temporary adhesive layer 37 is formed in an opening (25A) that is formed in the build-up insulating layer 25. The temporary adhesive layer 37 is arranged on the metal plate 15. An outer edge of the metal plate 15 protrudes outward from the temporary adhesive layer 37. As illustrated in FIG. 6A, a copper foil (25C) is laminated on the build-up insulating layer 25 and the temporary adhesive layer 37 and thereafter, the resulting substrate is hot-pressed. In this case, a clearance 36 between the metal plate 15 and an inner peripheral surface of the accommodation hole 35 is filled with resin that forms the build-up insulating layers (25, 25).

(9) As illustrated in FIG. 6B, electrical conductive via formation holes (38A) and thermal conductive via formation holes (38B) are formed by irradiating, for example, CO2 laser from the front side and the back side of the core substrate 21 to the build-up insulating layers 25 and the copper foils (25C). In this case, the core conductor layers 22 are exposed by the electrical conductive via formation holes (38A), and the metal plate 15 is exposed by the thermal conductive via formation holes (38B).

(10) An electroless plating treatment is performed. An electroless plating film (not illustrated in the drawings) is formed on the copper foil (25C), inner walls of the electrical conductive via formation holes (38A) and inner walls of the thermal conductive via formation holes (38B).

(11) As illustrated in FIG. 6C, a plating resist 39 of a predetermined pattern is formed on the electroless plating film on the copper foil (21C).

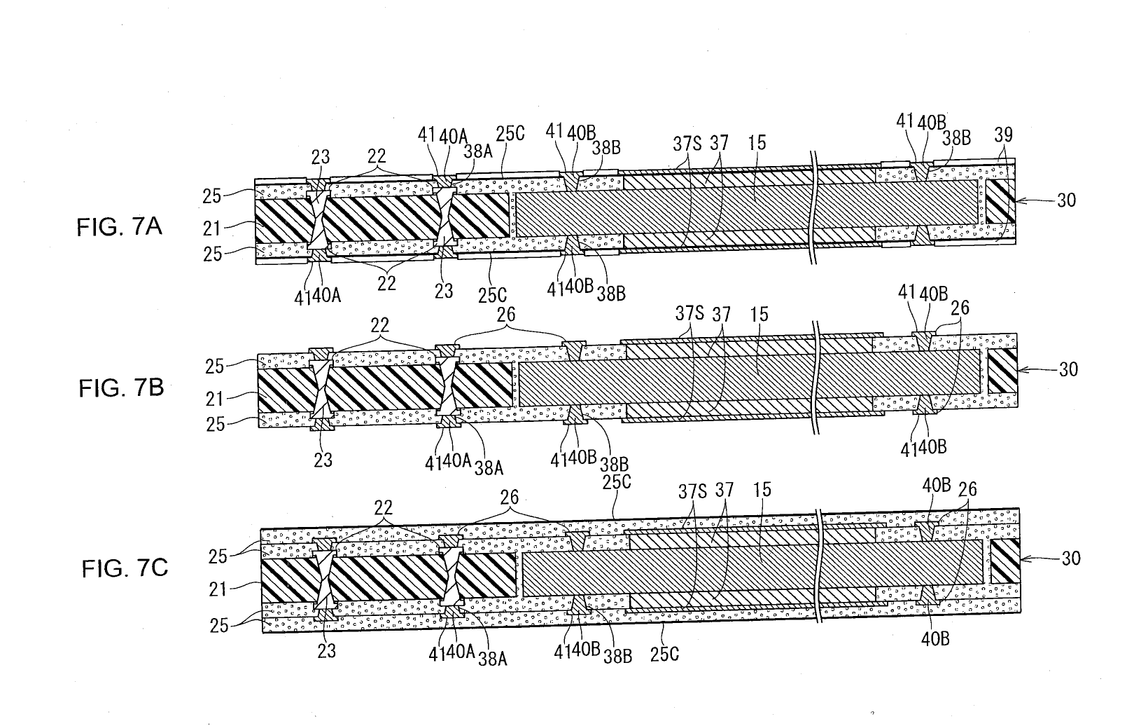

(12) As illustrated in FIG. 7A, an electrolytic plating treatment is performed. The electrical conductive via formation holes (38A) and the thermal conductive via formation holes (38B) are filled with electrolytic plating and the electrical conductive vias (40A) and the thermal conductive vias (40B) are formed. Further, an electrolytic plating film 41 is formed on a portion of the electroless plating film (not illustrated in the drawings) on the build-up insulating layer 25, the portion being exposed from the plating resist 39.

(13) The plating resist 39 is removed and the electroless plating film (not illustrated in the drawings) below the plating resist 39 is removed. As illustrated in FIG. 7B, by the remaining electrolytic plating film 41, electroless plating film and copper foil (25C) (see FIG. 7A; illustration thereof is omitted in FIG. 7B), a build-up conductor layer 26 is formed on the build-up insulating layer 25 and a stopper layer (37S) is formed on the temporary adhesive layer 37. Specifically, the stopper layer (37S) is formed to have a size such that the stopper layer (37S) slightly protrudes outward from the temporary adhesive layer 37.

(14) As illustrated in FIG. 7C, a build-up insulating layer 25 and a copper foil (25C) are laminated on the build-up conductor layer 26 and the stopper layer (37S) from the front side and the back side of the core substrate 21.

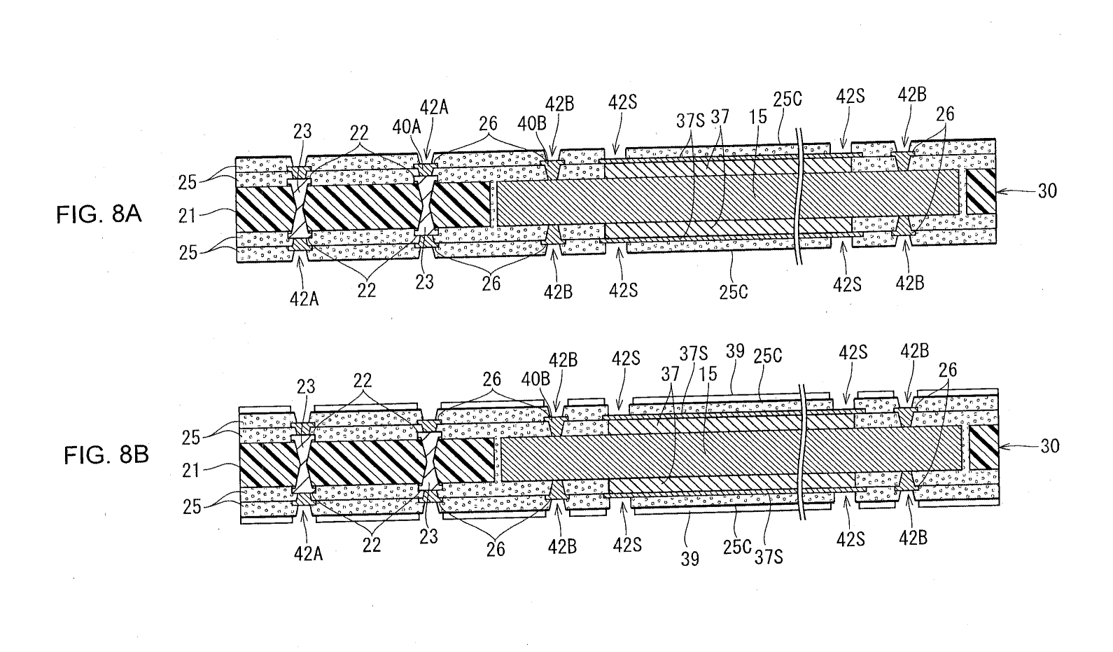

(15) As illustrated in FIG. 8A, by irradiating, for example, CO2 laser to the build-up insulating layer 25 and the copper foil (25C), which are positioned outermost, an electrical conductive via formation hole (42A) and a thermal conductive via formation hole (42B) are formed and a slit (42S) is formed along an outer edge of the temporary adhesive layer 37, and the stopper layer (37S) is exposed.

(16) An electroless plating treatment is performed. An electroless plating film (not illustrated in the drawings) is formed on the copper foil (25C), on inner surfaces of the electrical conductive via formation hole (42A) and the thermal conductive via formation hole (42B) and on an inner surface of the slit (42S).

(17) As illustrated in FIG. 8B, a plating resist 39 of a predetermined pattern is formed on the electroless plating film on the copper foil (21C).

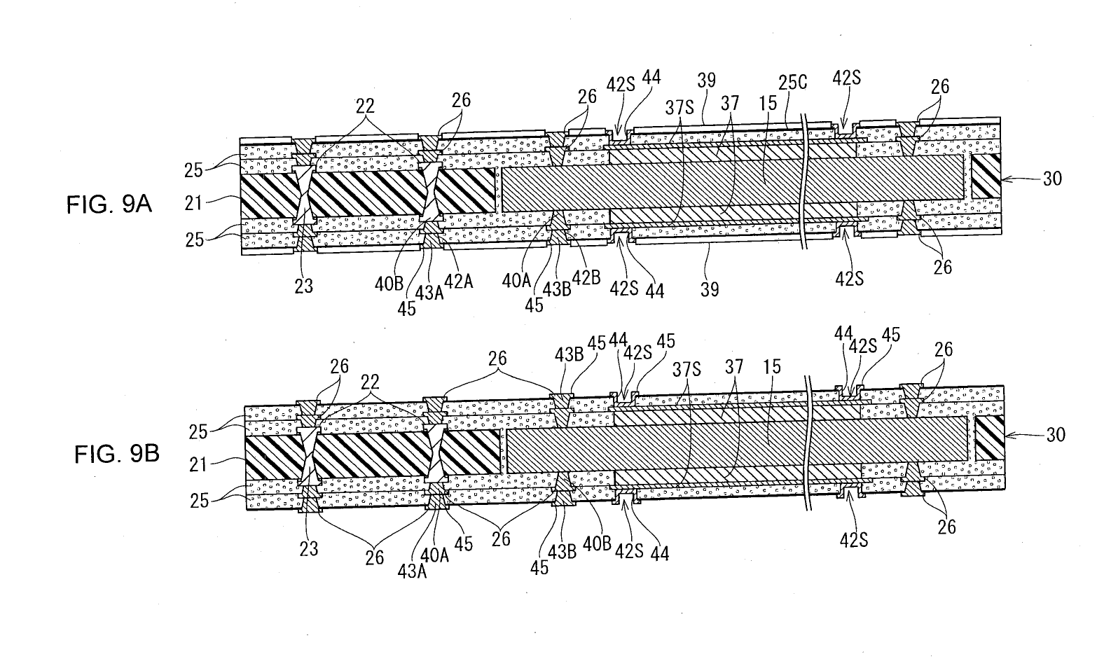

(18) An electrolytic plating treatment is performed. As illustrated in FIG. 9A, the electrical conductive via formation hole (42A) and the thermal conductive via formation hole (42B) are filled with the electrolytic plating and the electrical conductive via (43A) and the thermal conductive via (43B) are formed; and an in-slit plating film 44 is formed in the slit (42S). Further, an electrolytic plating film 45 is formed on a portion of the electroless plating film (not illustrated in the drawings) on the copper foil (25C), the portion being exposed from the plating resist 39.

(19) The plating resist 39 is removed, and the electroless plating film (not illustrated in the drawings) and the copper foil (25C), which are below the plating resist 39, are removed. As illustrated in FIG. 9B, a build-up conductor layer 26 is formed by the remaining electrolytic plating film 45, electroless plating film and copper foil (25C).

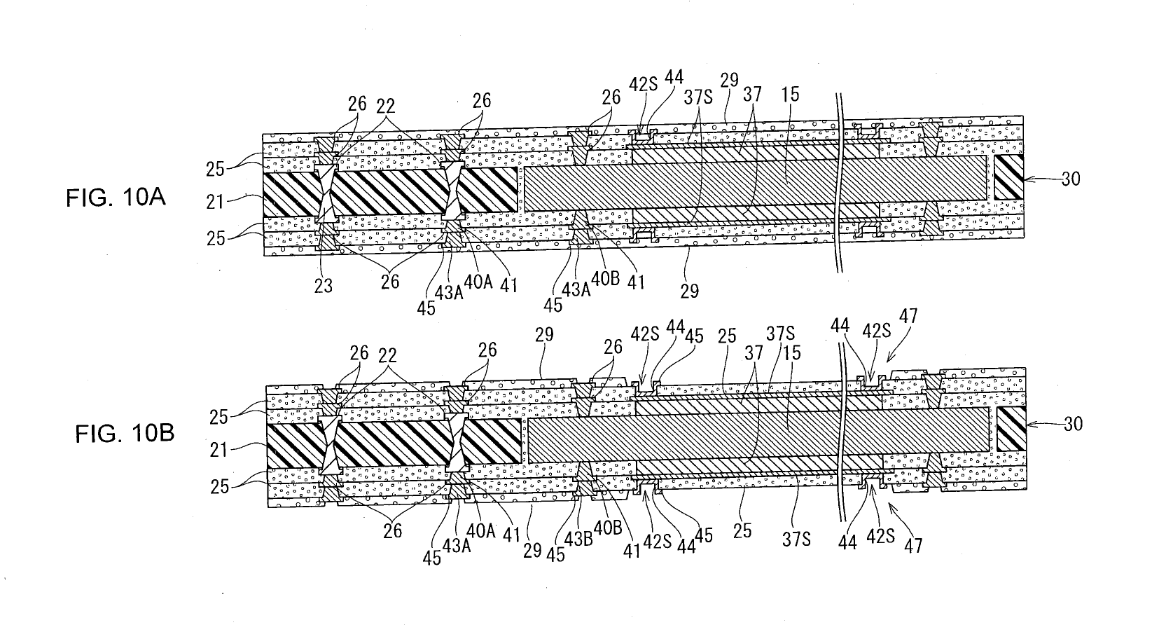

(20) As illustrated in FIG. 10A, the solder resist layers (29, 29) are respectively laminated on the build-up conductor layers (26, 26) from both the front side and the back side of the core substrate 21.

(21) As illustrated in FIG. 10B, a tapered pad hole is formed at a predetermined place on the solder resist layer 29 and a portion of the build-up conductor layer 26 is exposed from the solder resist layer 29 to become a pad; and a take-out hole 47 is formed that exposes portions of the outermost build-up conductor layer 26 and the outermost build-up insulating layer 25 that overlap with the temporary adhesive layer 37.

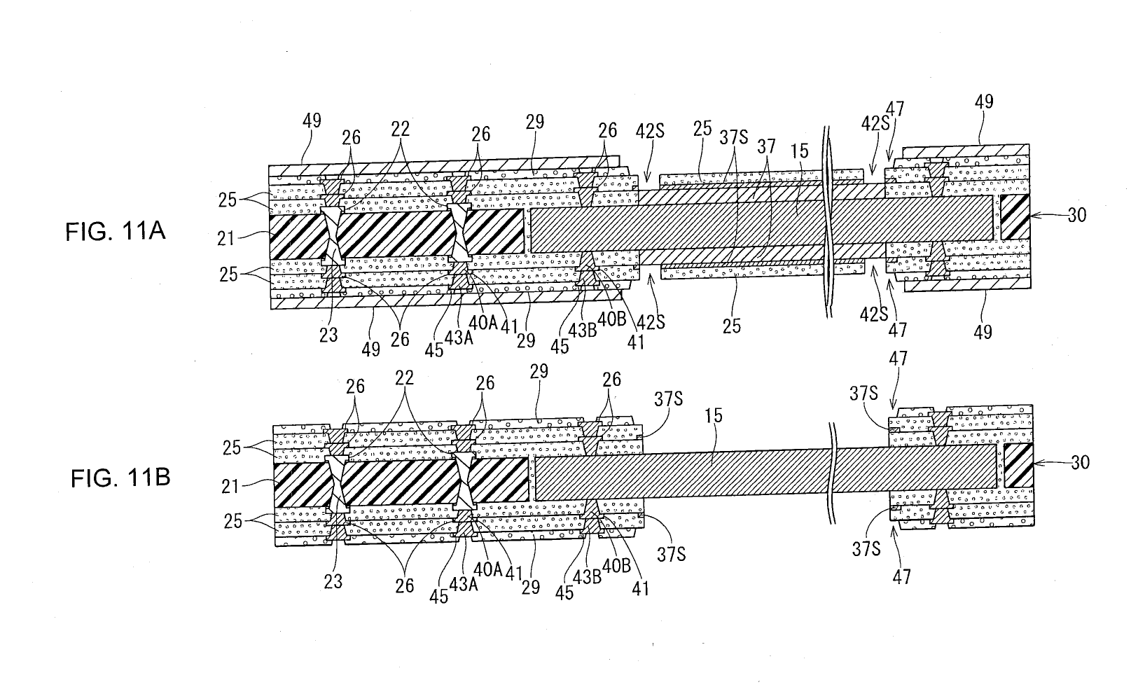

(22) A masking process and an etching process are performed. As illustrated in FIG. 11A, a mask resist layer 49 of a predetermined pattern is formed on the solder resist layer 29. The electrolytic plating film 45 in the take-out hole 47, and the in-slit plating film 44 and the stopper layer (37S) in the slit (42S), are removed.

(23) As illustrated in FIG. 11B, the mask resist layer 49 is removed; and the temporary adhesive layer 37 and the build-up insulating layer 25 that is laminated on the temporary adhesive layer 37 are taken out from the take-out hole 47, and a portion of the metal plate 15 is exposed.

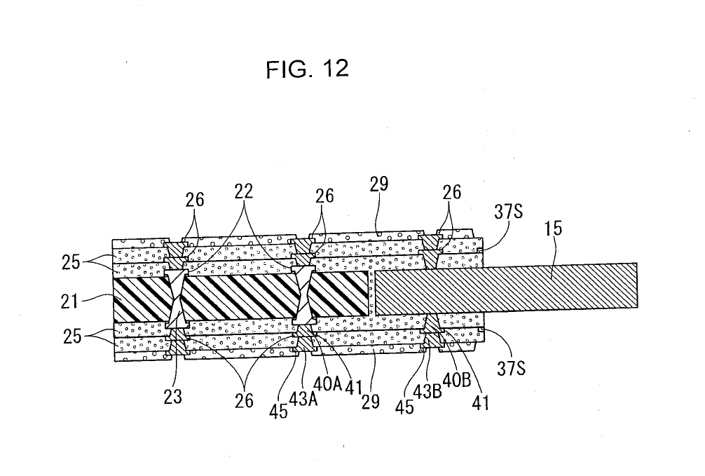

(24) As illustrated in FIG. 12, the exposed portion of the metal plate 15 is cut. As a result, the circuit substrate 20 is completed. Specifically, as illustrated in FIG. 12, a portion of the stopper layer (37S) remains between the build-up insulating layers 25 on the side where the metal plate 15 is exposed. However, in FIG. 3, illustration of this portion of the stopper layer (37S) is omitted.

The description about the structure and the manufacturing method of the electronic circuit apparatus 10 of the present embodiment is as given above. Next, an operation effect of the electronic circuit apparatus 10 is described.

In the electronic circuit apparatus 10 of the present embodiment, the metal plate 15 that forms a portion of the inner layer of the circuit substrate 20 protrudes from one side of the circuit substrate 20 and is connected to the heat pipe 13. Therefore, heat from the semiconductor element 11 can be transmitted via the metal plate 15 to the heat pipe 13, and the circuit substrate 20 can be made thinner than a conventional circuit substrate with a built-in heat pipe 13. In addition, the interior of the circuit substrate 20 is also used as a heat dissipation path and thus heat dissipation efficiency of the entire electronic circuit apparatus 10 can be increased.

Further, in the present embodiment, the metal plate 15 is arranged only in a region of a portion of the circuit substrate 20 including a position below the semiconductor element 11. Therefore, a heat dissipation path from the semiconductor element 11 to the metal plate 15 is shortened and heat transmission efficiency is increased. In addition, the circuit substrate 20 has the thermal conductive via (43B) that extends in a thickness direction at a position below the semiconductor element 11 and is conductively connected to the metal plate 15. Therefore, heat transmission efficiency from the semiconductor element 11 toward the metal plate 15 can be further improved.

### Second Embodiment

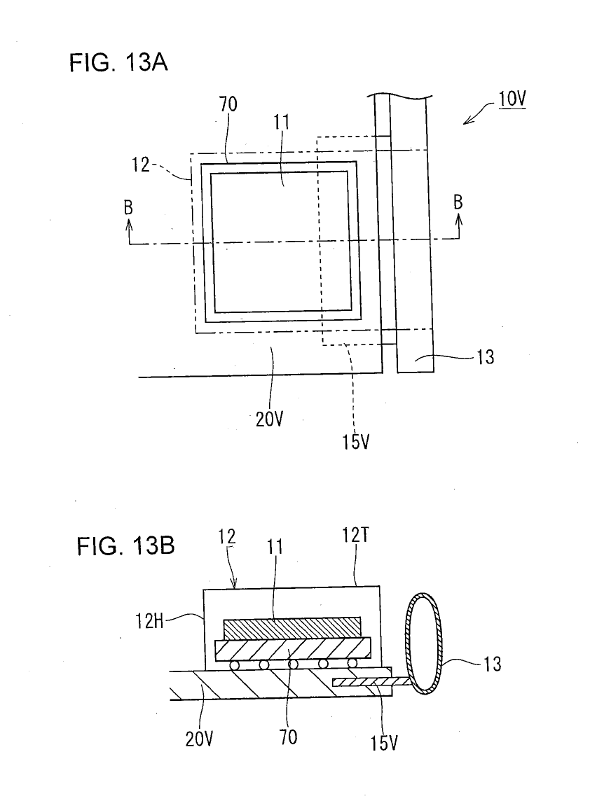

In the following, a second embodiment of the present invention is described based on FIG. 13-21. As illustrated in FIG. 13A, an electronic circuit apparatus (10V) of the present embodiment includes a circuit substrate (20V) and a relay circuit substrate 70 that is mounted on the circuit substrate (20V). In the present embodiment, the circuit substrate (20V) is a motherboard and the relay circuit substrate 70 is a CSP (Chip Size Package) having the same size as a chip. The semiconductor element 11 as a “heat generating component” according to an embodiment of the present invention is mounted on the relay circuit substrate 70.

As illustrated in FIG. 13B, the relay circuit substrate 70 is sealed by the shield can 12 described above in the first embodiment. The surrounding wall (12H) of the shield can 12 is arranged so as to surround four sides of the relay circuit substrate 70, and the leg portion of the surrounding wall (12H) is fixed on the circuit substrate (20V).

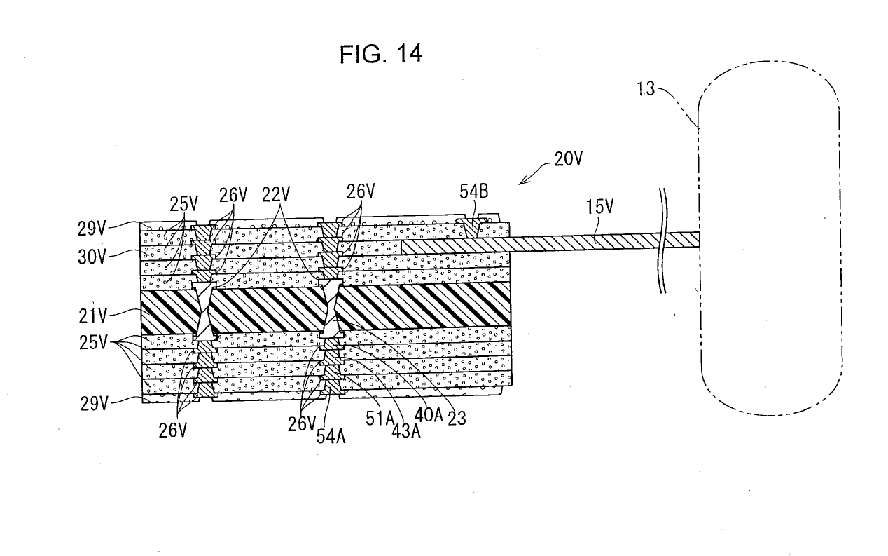

As illustrated in FIG. 14, similar to the first embodiment, the circuit substrate (20V) has a multilayer structure in which build-up insulating layers (25V), build-up conductor layers (26V) and a solder resist layer (29V) are laminated on both the front and back surfaces of a core substrate (21V). The build-up insulating layers (25V) and the build-up conductor layers (26V) are alternately laminated, and the outermost build-up conductor layers (26V) are respectively covered by the solder resist layers (29V). With regard to thicknesses of the layers, the core substrate (21V) has a thickness of about 100 μm; the build-up insulating layers (25V) each have a thickness of about 50 μm; the build-up conductor layers (26V) each have a thickness of about 20-25 μm; and the solder resist layers 29V each have a thickness of about 15 μm.

Electrical conductive vias (40A, 43A, 51A, 54A) are formed in the build-up insulating layers (25V). The innermost build-up conductor layer 26V, which is closest to the core substrate 21V, and a core conductor layer 22 are connected by the electrical conductive via (40A), and the build-up conductor layers (26, 26) that are adjacent to each other in a lamination direction are connected by the electrical conductive vias (43A, 51A, 54A).

In the circuit substrate (20V) of the present embodiment, a build-up insulating layer (25V) is a metal plate built-in insulating layer (30V) that has a built-in metal plate 15. Specifically, a portion of the metal plate (15V) forms a region ranging from a portion of the build-up insulating layer (25V) positioned below the semiconductor element 11 to an edge on the side close to the heat pipe 13; and the rest of the metal plate (15V) protrudes from a side surface of the circuit substrate 20 and is exposed to the outside. The portion of the metal plate (15V) that is exposed to the outside of the circuit substrate 20V is thermally connected to the heat pipe 13, for example, by soldering. A thickness of the metal plate (15V) is substantially the same as the thickness of the build-up insulating layer (25V) and is about 50 μm.

The metal plate built-in insulating layer (30V) is arranged on a front side rather than at a center in a thickness direction of the circuit substrate (20V). In the example illustrated in FIG. 14, the four build-up insulating layers (25V) are laminated on each of the front and sides of the core substrate 21. The build-up insulating layer (25V) on an inner side next to the outermost build-up insulating layer (25V) is the metal plate built-in insulating layer (30V). Further, a thermal conductive via (54B) is formed in a portion of the outermost build-up insulating layer (25V) that overlaps with the metal plate built-in insulating layer (30V). The outermost build-up conductor layer 26V and the metal plate 15V are connected by the thermal conductive via (40B).

Other structures of the electronic circuit apparatus (10V) of the present embodiment are the same as those of the first embodiment, and thus are indicated using the same reference numeral symbols and description thereof is omitted. Next, a method for manufacturing the electronic circuit apparatus (10V) is described.

Similar to the first embodiment, in the method for manufacturing the electronic circuit apparatus (10V), first, using a method, the semiconductor element 11 is mounted on a CSP as the relay circuit substrate 70, and the CSP is solder-connected on a motherboard as the circuit substrate (20V). Then, the shield can 12 is fixed on the circuit substrate (20V), and the metal plate 15V that protrudes from the circuit substrate (20V) penetrates through the shield can 12 and is connected to the heat pipe 13. Thereby, the electronic circuit apparatus (10V) is obtained.

The circuit substrate (20V) is manufactured as follows.

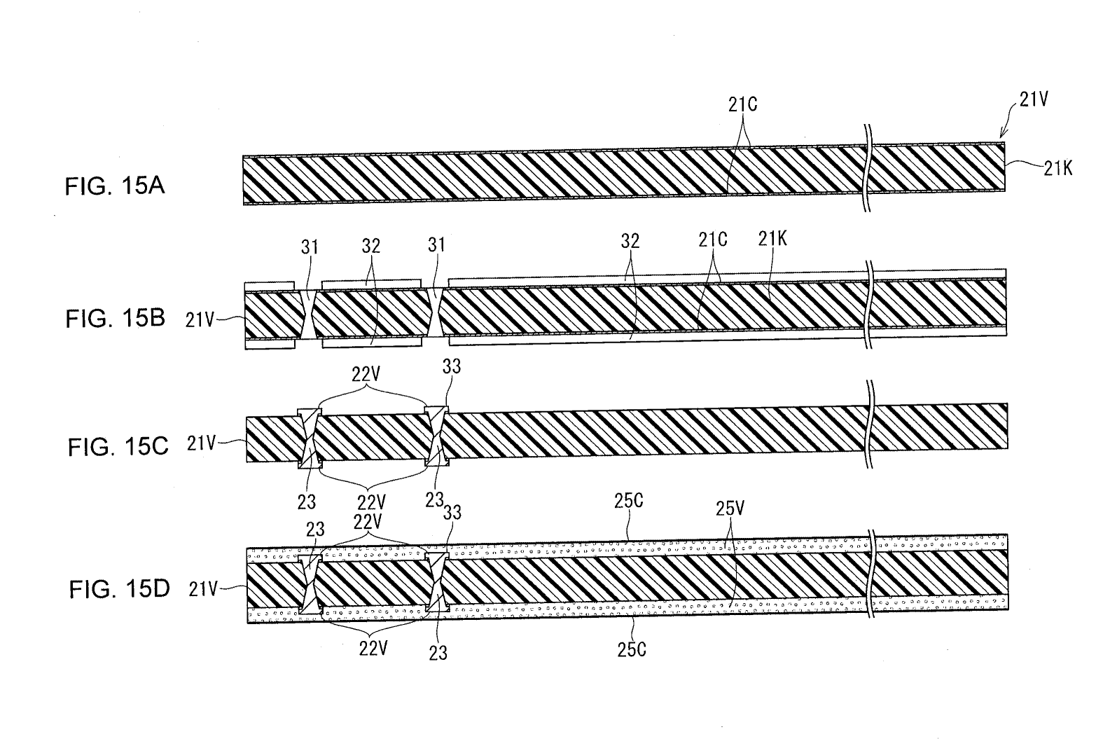

(1) As illustrated in FIG. 15A, first, the core substrate (21V) is prepared. The core substrate (21V) is obtained by laminating a copper foil (21C) on both front and back surfaces of an insulating base material (21K) that is made of epoxy resin or BT (bismaleimide triazine) resin and a reinforcing material such as a glass cloth.

(2) A core through hole 31 is drilled by irradiating, for example, CO2 laser to the core substrate (21V) from the front side and the back side. Next, an electroless plating treatment is performed. An electroless plating film (not illustrated in the drawings) is formed on the copper foil (21C) and on an inner surface of the core through hole 31. Then, as illustrated in FIG. 15B, a plating resist 32 of a predetermined pattern is formed on the electroless plating film on the copper foil (21C).

(3) An electrolytic plating treatment is performed. The core through hole 31 is filled with electrolytic plating and a through-hole conductor 23 is formed. Further, electrolytic plating films (33, 33) are formed on portions of the electroless plating film (not illustrated in the drawings) on both the front and back surfaces of the core substrate (21V), the portions being exposed from the plating resist 32. Next, the plating resist 32 is peeled off, and the electroless plating film (not illustrated in the drawings) and the copper foil (21C), which are below the plating resist 32, are removed. As illustrated in FIG. 15C, a core conductor layer (22V) is formed on each of the front and back surfaces of the core substrate (21V) by the remaining electrolytic plating film 32, electroless plating film and copper foil (21C) (see FIG. 15B; illustration thereof is omitted in FIG. 15C).

(4) As illustrated in FIG. 15D, a prepreg (a resin sheet of a B-stage formed by impregnating a core material with resin) as a build-up insulating layer (25V) and a copper foil (25C) are laminated on the core conductor layer (22V) on each of the front and back surfaces of the core substrate (21V) and thereafter, the resulting substrate is hot-pressed. In this case, a portion where the core conductor layer (22V) is not formed is filled with the prepreg. Instead of the prepreg, it is also possible to use a resin film that does not contain a core material as the build-up insulating layer (25V). In this case, without laminating a copper foil, a conductor layer can be directly formed on a surface of the resin film using a semi-additive method.

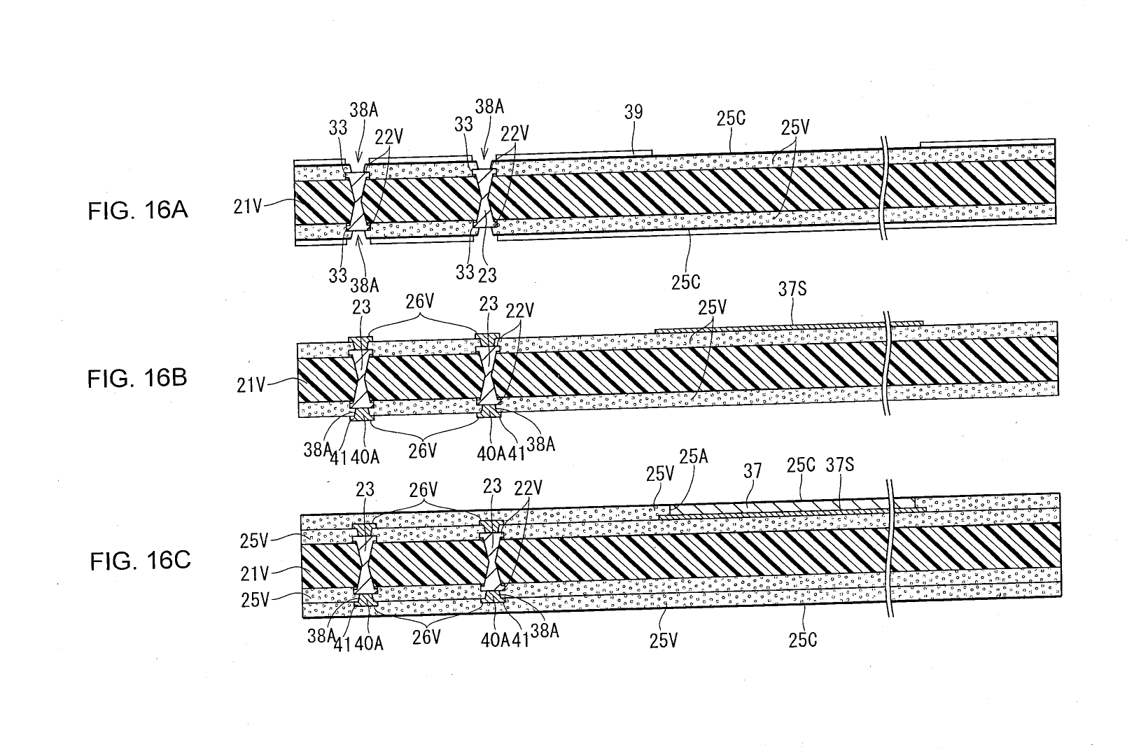

(5) CO2 laser is irradiated from the front side and the back side of the core substrate (21V) to the copper foils (25C) and electrical conductive via formation holes (38A) that penetrate through the copper foils (25C) and the build-up insulating layers (25V) are formed. Then, an electroless plating treatment is performed. An electroless plating film (not illustrated in the drawings) is formed on the copper foils (25C) and on inner surfaces of the electrical conductive via formation holes (38A). Next, as illustrated in FIG. 16A, a plating resist 39 of a predetermined pattern is formed on the electroless plating film on the copper foil (25C).

(6) An electrolytic plating treatment is performed. The electrical conductive via formation holes (38A) are filled with electrolytic plating and the electrical conductive vias (40A) are formed; and an electrolytic plating film 41 is formed on a portion of the electroless plating film (not illustrated in the drawings) on the copper foil (25C), the portion being exposed from the plating resist 39. Next, the plating resist 39 is removed using 5% NaOH, and the electroless plating film (not illustrated in the drawings) and the copper foil (25C), which are below the plating resist 39, are removed. As illustrated in FIG. 16B, a build-up conductor layer (26V) is formed on the build-up insulating layer (25V) by the remaining electrolytic plating film 41, electroless plating film and copper foil (25C) (see FIG. 16A; illustration thereof is omitted in FIG. 16B). In this case, a stopper layer (37S) is also formed on the front side build-up insulating layer (25V) by the electrolytic plating film 41, the electroless plating film and the copper foil (25C).

(7) As illustrated in FIG. 16C, a build-up insulating layer (25V) having an opening (25A) is laminated on the build-up conductor layer (26V) from the front side of the core substrate (21V) (upper side in FIG. 16C), and the opening (25A) is filled with a temporary adhesive layer 37. A copper foil (25C) is laminated on the build-up insulating layer 25 and on the temporary adhesive layer 37. In this case, the temporary adhesive layer 37 is arranged on the stopper layer (37S). Further, a build-up insulating layer (25V) and a copper foil (25C) are laminated on the build-up conductor layer (26V) from the back side of the core substrate 21.

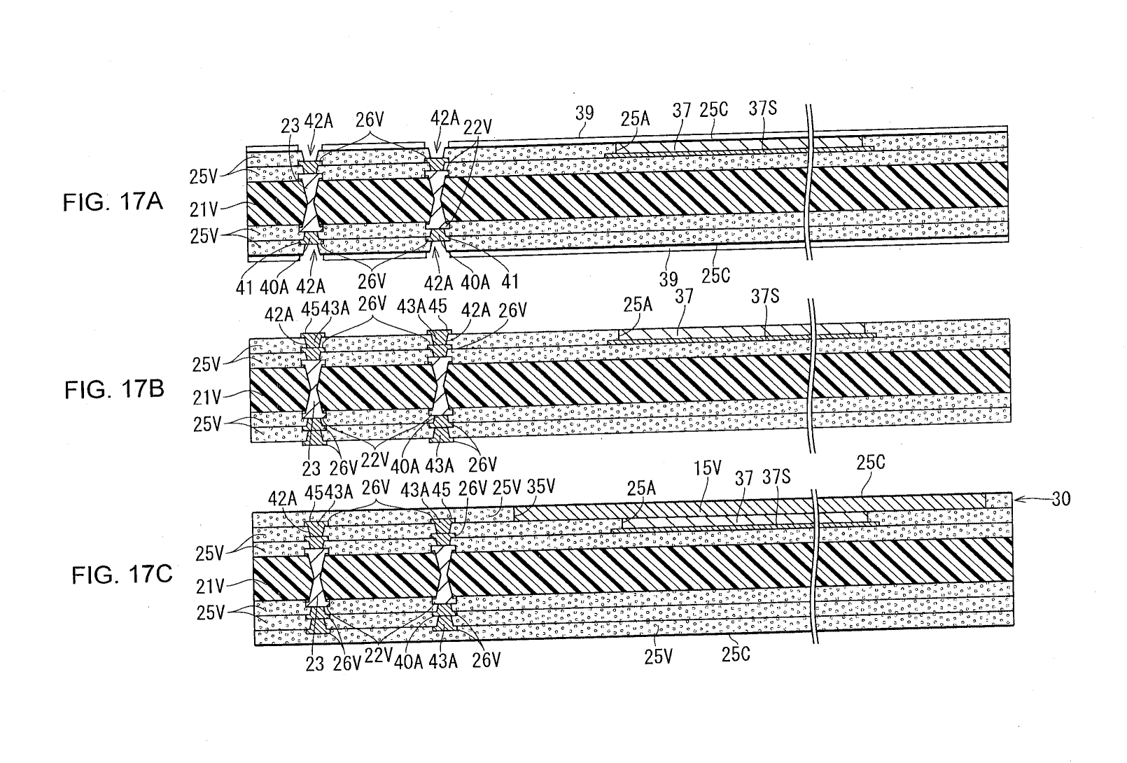

(8) CO2 laser is irradiated from the front side and the back side of the core substrate (21V) to the copper foils (25C) and electrical conductive via formation holes (42A) that penetrate through the copper foils (25C) and the build-up insulating layers (25V) are formed. Then, an electroless plating treatment is performed. An electroless plating film (not illustrated in the drawings) is formed on the copper foils (25C) and on inner surfaces of the electrical conductive via formation holes (42A). Next, as illustrated in FIG. 17A, a plating resist 39 of a predetermined pattern is formed on the electroless plating film on the copper foils (25C).

(9) An electrolytic plating treatment is performed. The electrical conductive via formation holes (42A) are filled with electrolytic plating and the electrical conductive vias (43A) are formed; and an electrolytic plating film 45 is formed on a portion of the electroless plating film (not illustrated in the drawings) on the copper foil (25C), the portion being exposed from the plating resist 39. Next, the plating resist 39 is removed using 5% NaOH, and the electroless plating film (not illustrated in the drawings) and the copper foil (25C), which are below the plating resist 39, are removed. As illustrated in FIG. 17B, a build-up conductor layer (26V) is formed on the build-up insulating layer (25V) by the remaining electrolytic plating film 45, electroless plating film and copper foil (25C) (see FIG. 17A; illustration thereof is omitted in FIG. 17B).

(10) As illustrated in FIG. 17C, a build-up insulating layer (25V) having an accommodation hole (35V) is laminated on the build-up conductor layer (26V) from the front side of the core substrate (21V) (upper side of FIG. 17C), and the accommodation hole (35V) is filled with the metal plate (15V) and the metal plate built-in insulating layer (30V) is formed. Further, a copper foil (25C) is laminated on the metal plate built-in insulating layer (30V). Further, a build-up insulating layer (25V) and a copper foil (25C) are laminated on the build-up conductor layer (26V) from the back side of the core substrate (21V).

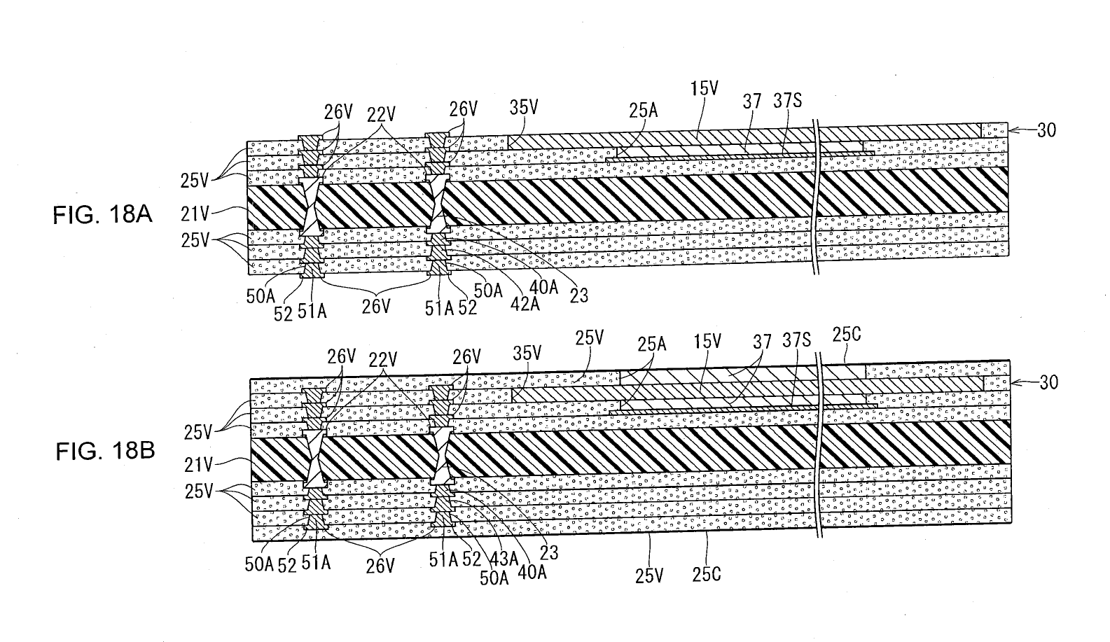

(11) By the same processing as that illustrated in FIG. 16C-17B, as illustrated in FIG. 18A, build-up conductor layers (26V) are respectively laminated on the build-up insulating layers (25V) from the front side and the back side of the core substrate (21V). Specifically, CO2 laser is irradiated from the front side and the back side of the core substrate (21V) to the copper foils (25C), and electrical conductive via formation holes (50A) that penetrate through the copper foils (25C) and the build-up insulating layers (25V) are formed. Then, an electroless plating treatment is performed. An electroless plating film (not illustrated in the drawings) is formed on the copper foils (25C) and on inner surfaces of the electrical conductive via formation holes (50A). Next, a plating resist of a predetermined pattern is formed on the electroless plating film on the copper foils (25C). Thereafter, by an electrolytic plating treatment, the electrical conductive vias (51A) are formed in the electrical conductive via formation holes (50A); and an electrolytic plating film 52 is formed on a portion exposed from the plating resist, and a build-up conductor layer (26V) is formed on the build-up insulating layer (25V) by the remaining electrolytic plating film 52, electroless plating film and copper foil (25C) (see FIG. 17C; illustration thereof is omitted in FIG. 18A).

(12) By the same processing as illustrated in FIG. 17B, as illustrated in FIG. 18B, a build-up insulating layer (25V) having an opening (25A) is laminated on the build-up conductor layer (26V) from the front side of the core substrate 21V, and the opening (25A) is filled with a temporary adhesive layer 37. A copper foil (25C) is laminated on the build-up insulating layer 25 and on the temporary adhesive layer 37. Further, a build-up insulating layer (25V) and a copper foil (25C) are laminated on the build-up conductor layer (26V) from the back side of the core substrate 21.

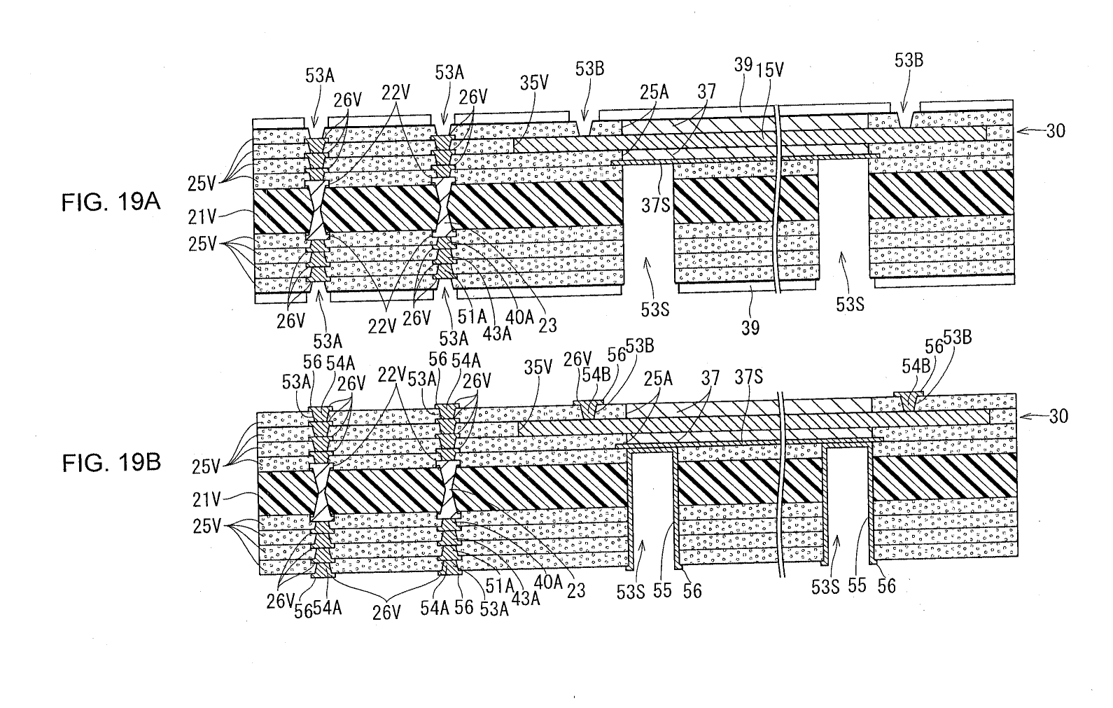

(13) As illustrated in FIG. 19A, an electrical conductive via formation hole (53A) and a thermal conductive via formation hole (53B) are formed by irradiating CO2 laser from the front side of the core substrate (21V) to the build-up insulating layer (25V) and the copper foil (25C). Further, CO2 laser is irradiated from the back side of the core substrate (21V) to the build-up insulating layer (25V) and the copper foil 25C. An electrical conductive via formation hole (53A) is formed, and a slit (53S) is formed along an outer edge of the temporary adhesive layer 37 and the stopper layer (37S) is exposed. Next, an electroless plating treatment is performed. An electroless plating film (not illustrated in the drawings) is formed on the copper foil (25C), on inner surfaces of the electrical conductive via formation hole (53A) and the thermal conductive via formation hole (53B) and on an inner surface of the slit (53S). Thereafter, a plating resist 39 of a predetermined pattern is formed on the electroless plating film on the copper foils (25C).

(14) An electrolytic plating treatment is performed. The electrical conductive via formation hole (53A) and the thermal conductive via formation hole (53B) are filled with the electrolytic plating and the electrical conductive via (54A) and the thermal conductive via (54B) are formed; and an in-slit plating film 55 is formed in the slit (53S). Further, an electrolytic plating film 56 is formed on a portion of the electroless plating film (not illustrated in the drawings) on the copper foil (25C), the portion being exposed from the plating resist 39. Next, the plating resist 39 is removed, and the electroless plating film (not illustrated in the drawings) and the copper foil (25C), which are below the plating resist 39, are removed. As illustrated in FIG. 19B, a build-up conductor layer (26V) is formed by the remaining electrolytic plating film 56, electroless plating film and copper foil (25C).

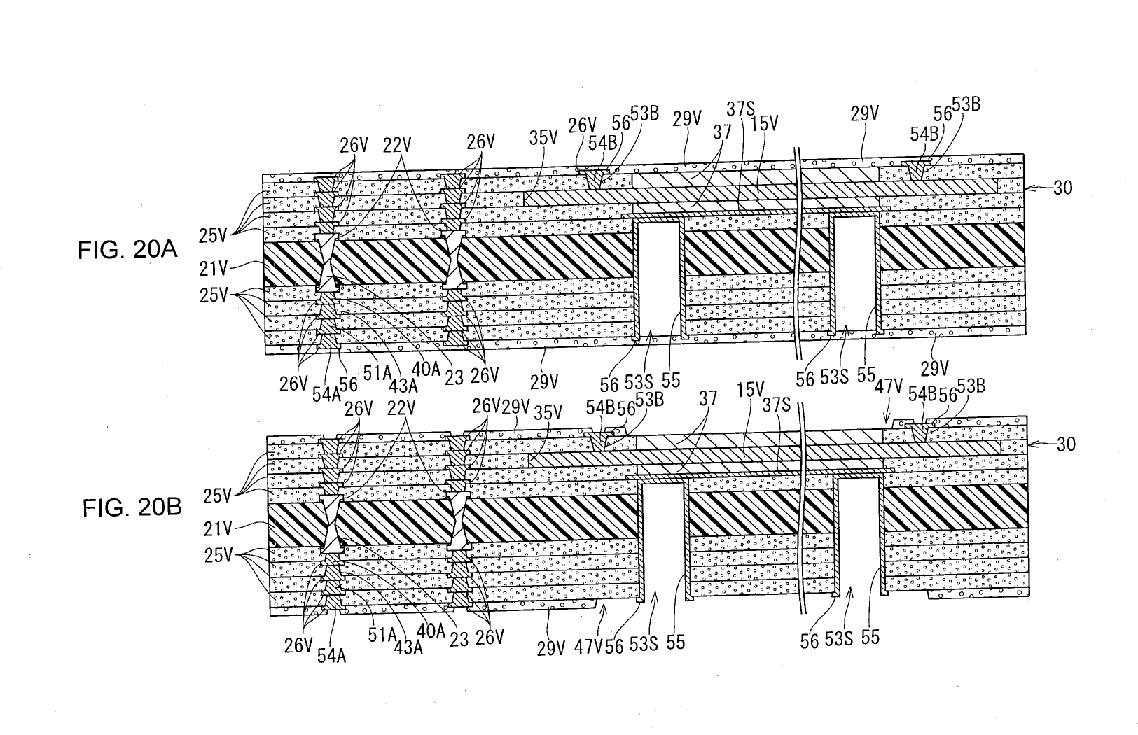

(15) As illustrated in FIG. 20A, the solder resist layers (29V) are respectively laminated on the build-up conductor layers (26V) from the front side and the back side of the core substrate (21V).

(16) As illustrated in FIG. 20B, tapered pad holes are formed at predetermined places in the solder resist layers (29V) and portions of the outermost build-up conductor layers (26V) are exposed from the solder resist layers (29V) to become pads; and take-out holes (47V) that expose portions of the outermost build-up insulating layers (25V) that overlap with the temporary adhesive layer 37 are respectively formed in the solder resist layers (29V).

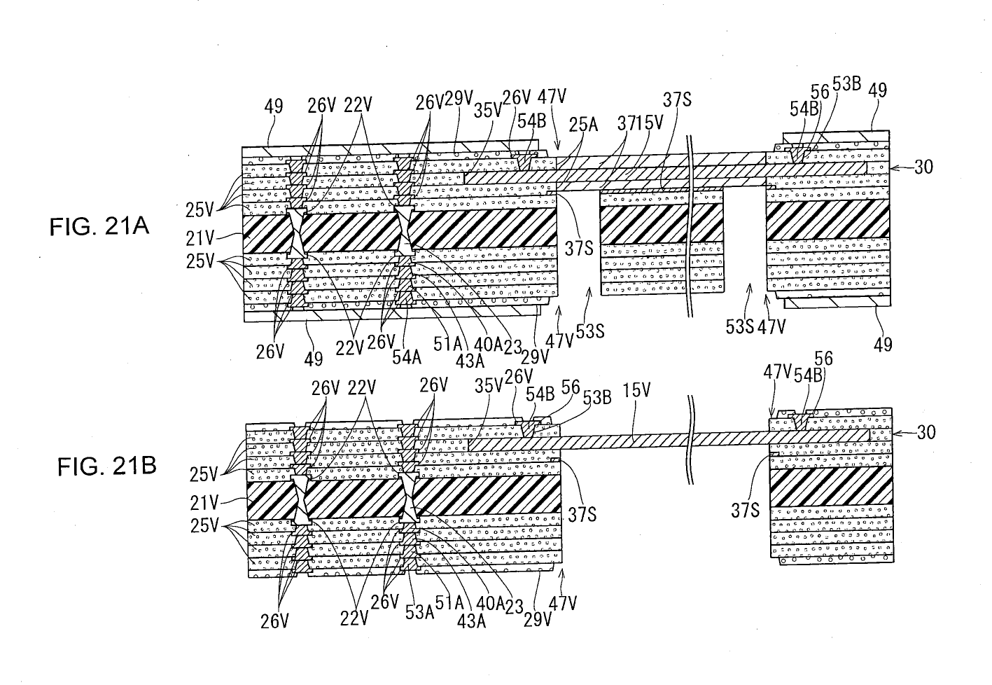

(17) A masking process and an etching process are performed. As illustrated in FIG. 21A, mask resist layers 49 of predetermined patterns are respectively formed on the solder resist layers (29V). The electrolytic plating films 56 in the take-out holes (47V), and the in-slit plating film 55 and the stopper layer (37S) in the slit (53S) are removed.

(18) As illustrated in FIG. 21B, the temporary adhesive layers 37 and the build-up insulating layers (25V) that are laminated on the temporary adhesive layers 37 are taken out from the take-out holes 47V, and a portion of the metal plate (15V) is exposed.

(19) The exposed portion of the metal plate (15V) is cut. As a result, the circuit substrate (20V) is completed.

The description about the structure and the manufacturing method of the electronic circuit apparatus (10V) of the present embodiment is as given above. Next, an operation effect of the electronic circuit apparatus (10V) is described.

In the electronic circuit apparatus (10V) of the present embodiment, similar to the first embodiment, the circuit substrate (20V) can be made thin and heat from the semiconductor element 11 can be transmitted via the metal plate (15V) to the heat pipe 13.

Further, in the present embodiment, the metal plate (15V) is arranged on the side close to the semiconductor element 11 rather than at the center in the thickness direction of the circuit substrate (20V). Therefore, a distance from the semiconductor element 11 to the metal plate (15V) is shortened and the heat transmission efficiency is improved.

### Other Embodiments

The present invention is not limited to the above-described embodiment. For example, embodiments described below are also included in the technical scope of the present invention. Further, in addition to the embodiments described below, the present invention can also be embodied in various modified forms within the scope without departing from the spirit of the present invention.

(1) In the first embodiment, the metal plate 15 is arranged at a center in a thickness direction of the circuit substrate 20. However, it is also possible that the metal plate 15 is arranged on the side close to the semiconductor element 11 rather than at the center in the thickness direction of the circuit substrate 20. The present structure, similar to the second embodiment, can be realized by forming a portion of the build-up insulating layer 25 with the metal plate 15.

(2) In the second embodiment and in the structure of (1), it is also possible that the circuit substrate (20, 20V) is a so-called coreless substrate that does not have a core substrate 21.

(3) In the above embodiments, examples are described in which the heat pipe 13 is used as the “external cooling member” according to an embodiment of the present invention. However, it is also possible that a heat sink is used as the “external cooling member” according to an embodiment of the present invention. Further, instead of the “external cooling member,” it is also possible that an aluminum member, a graphite member or the like is used as the “external heat dissipation member” according to an embodiment of the present invention.

A conventional electronic circuit apparatus may have a problem that it is difficult to make a thin circuit substrate. An electronic circuit apparatus according to an embodiment of the present invention allows a circuit substrate on which a heat generating component is mounted to be made thin and enables heat dissipation or cooling of the heat generating component, and another embodiment of the present invention provides a method for manufacturing such an electronic circuit apparatus.

An electronic circuit apparatus according to an embodiment of the present invention includes: a circuit substrate; a heat generating component that is mounted on the circuit substrate; a metal plate that forms a portion of an inner layer of the circuit substrate and protrudes from a side surface of the circuit substrate to be exposed to outside; and an external heat dissipation member or an external cooling member that is connected to an exposed portion of the metal plate.

Obviously, numerous modifications and variations of the present invention are possible in light of the above teachings. It is therefore to be understood that within the scope of the appended claims, the invention may be practiced otherwise than as specifically described herein.

What is claimed is:

1. An electronic circuit apparatus, comprising:
a circuit substrate;
a heat generating component positioned on the circuit substrate;
a metal plate forming a portion of an inner layer of the circuit substrate and protruding from a side surface of the circuit substrate such that the metal plate has an exposed portion exposed to outside the circuit substrate; and
an external component connected to the exposed portion of the metal plate and comprising one of an external heat dissipation component and an external cooling component.

2. An electronic circuit apparatus according to claim 1, wherein the external component comprises the external cooling component, and the exposed portion of the metal plate is connected to a heat pipe forming the external cooling component.

3. An electronic circuit apparatus according to claim 1, wherein the metal plate is positioned in a region including a downward position with respect to the heat generating component in the inner layer of the circuit substrate.

4. An electronic circuit apparatus according to claim 3, wherein the circuit substrate includes a heat conducting via structure connected to the metal plate such that the heat conducting via structure is extending in a thickness direction of the circuit substrate in the downward position with respect to the heat generating component.

5. An electronic circuit apparatus according to claim 1, further comprising:
a support substrate on which the circuit substrate is mounted; and
a shield component supported on the support substrate and shielding the circuit substrate.

6. An electronic circuit apparatus according to claim 5, wherein the shield component is positioned such that the shield component is enclosing four sides of the circuit component, and the metal plate is penetrating through the shield component.

7. An electronic circuit apparatus according to claim 1, further comprising:
a relay circuit substrate positioned on the circuit substrate such that the heat generating component is mounted on the relay circuit substrate; and
a shield component supported on the support substrate and shielding the relay circuit substrate.

8. An electronic circuit apparatus according to claim 1, wherein the metal plate is positioned such that the metal plate is a near side of the heat generating component with respect to a center of the circuit substrate in a thickness direction of the circuit substrate.

9. An electronic circuit apparatus according to claim 2, wherein the metal plate is positioned in a region including a downward position with respect to the heat generating component in the inner layer of the circuit substrate.

10. An electronic circuit apparatus according to claim 9, wherein the circuit substrate includes a heat conducting via structure connected to the metal plate such that the heat conducting via structure is extending in a thickness direction of the circuit substrate in the downward position with respect to the heat generating component.

11. An electronic circuit apparatus according to claim 2, further comprising:
a support substrate on which the circuit substrate is mounted; and
a shield component supported on the support substrate and shielding the circuit substrate.

12. An electronic circuit apparatus according to claim 11, wherein the shield component is positioned such that the shield component is enclosing four sides of the circuit component, and the metal plate is penetrating through the shield component.

13. An electronic circuit apparatus according to claim 2, further comprising:
a relay circuit substrate positioned on the circuit substrate such that the heat generating component is mounted on the relay circuit substrate; and
a shield component supported on the support substrate and shielding the relay circuit substrate.

14. An electronic circuit apparatus according to claim 2, wherein the metal plate is positioned such that the metal plate is a near side of the heat generating component with respect to a center of the circuit substrate in a thickness direction of the circuit substrate.

15. An electronic circuit apparatus according to claim 1, wherein the circuit substrate comprises a plurality of insulating layers, a plurality of conductor layers and a heat conducting via structure connected to the metal plate such that the heat conducting via structure is extending in a thickness direction of the circuit substrate.

16. A method for manufacturing an electronic circuit apparatus, comprising:
forming a circuit substrate having a metal plate forming a portion of an inner layer of the circuit substrate;
removing a portion of the circuit substrate such that the metal plate has an exposed portion exposed to outside the circuit substrate and protruding from a side surface of the circuit substrate;
connecting to the exposed portion of the metal plate an external component comprising one of an external heat dissipation component and an external cooling component; and
positioning a heat generating component on the circuit substrate.

17. A method for manufacturing an electronic circuit apparatus according to claim 16, wherein the forming of the circuit substrate comprises laminating a plurality of insulating layers and a plurality of conductor layers, and forming a heat conducting via structure connecting the metal plate and one of the conductor layers through at least one of the insulating layers.

18. A method for manufacturing an electronic circuit apparatus according to claim 16, wherein the forming of the circuit substrate comprises forming the metal plate in the circuit substrate such that the metal plate is positioned a near side of the heat generating component with respect to a center of the circuit substrate in a thickness direction of the circuit substrate.

19. A method for manufacturing an electronic circuit apparatus according to claim 17, wherein the forming of the circuit substrate comprises forming the metal plate in the circuit substrate such that the metal plate is positioned a near side of the heat generating component with respect to a center of the circuit substrate in a thickness direction of the circuit substrate.

20. A method for manufacturing an electronic circuit apparatus according to claim 16, wherein the forming of the circuit substrate comprises forming a heat conducting via structure connecting the metal plate and one of the conductor layers through at least one of the insulating layers.
